(19) United States
(12) Patent Application Publication
(10) Pub. No.: US 2007/0238225 A1
(43) Pub. Date: Oct. 11, 2007

(54) Phase change memory with improved temperature stability

(76) Inventor: Guy Wicker, Southfield, MI (US)

Correspondence Address: TROP PRUNER & HU, PC, 1616 S. VOSS ROAD, SUITE 750, HOUSTON, TX, 77057-2631, US

(21) Appl. No.: 11/400,632

(22) Filed: Apr. 7, 2006

(51) Int. Cl. H01L 21/82

(52) U.S. Cl. 438/128

(57) ABSTRACT

A phase change memory may be formed using a chalcogenide material that includes selenium. The inclusion of selenium improves the heat stability of the resulting memory device. The chalcogenide may also be a lean germanium composition.

### BACKGROUND

This invention relates generally to phase change memories.

Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between the different detectable states of local order across the entire spectrum between completely amorphous and completely crystalline states.

Typical materials suitable for such an application include various chalcogenide elements. The state of the phase change materials is also non-volatile. When the memory is set in either a crystalline, semi-crystalline, amorphous, or semi-amorphous state representing a resistance value, that value is retained until reprogrammed, even if power is removed. This is because the program value represents a phase or physical state of the memory (e.g., crystalline or amorphous).

### BRIEF DESCRIPTION OF THE DRAWINGS

FIG. 1 is schematic depiction of a phase change memory in accordance with one embodiment of the present invention; and

FIG. 2 is a system depiction in accordance with one embodiment of the present invention.

### DETAILED DESCRIPTION

Phase change memories use alloys containing germanium, antimony, and tellurium. These alloys are sometimes referred to as GST alloys. GST alloys offer relatively high speed crystallization and good dynamic range, but do not have exceptional data retention at high temperatures. While alloys with relatively less germanium, called germanium lean alloys, have dramatically better crystallization speed and better data retention, their resistance goes down, and their dynamic range suffers.

The addition of selenium improves data retention and increases the resistivity and dynamic range of lean germanium chalcogenide compositions. The speed of crystallization may decrease as selenium is added, but alloys with 10% selenium can crystallize in less than 50 nanoseconds. Significant amounts of selenium reduce the thermal conductivity of the chalcogenide alloy as well, which can reduce the heat leakage through the top electrodes in some device configurations.

Thus, in some embodiments of the present invention, a phase change memory may be made with an alloy including a relatively lean amount of germanium. As used herein, less than about 15% (atomic percent) germanium is a lean germanium composition. In some embodiments, selenium may be added in a range from 1 to 15% (atomic percent). In other embodiments, the selenium concentration may be from 3 to 12% (atomic percent) and, in still other embodiments, the selenium concentration is between about 3 and about 10% (atomic percent). In some embodiments, tellurium may be 20 to 40atomic percent of the alloy and antimony may be 30 to 60 atomic percent of the alloy. All percentages provided herein are atomic percents.

An alloy with improved thermal stability may be achieved with the addition of selenium. The thermal stability may improve about 4° C. per 1% (atomic percent) of selenium added. These alloys may also exhibit increased alloy resistivity, improved dynamic range, and lower thermal conductivity, as well as acceptable decreases in crystallization speed.

Suitable chalcogenide alloys, in accordance with some embodiments of the present invention, include Te₄₈Ge_{41.5}Sb₈Se_{2.5} or Te₄₄Ge₃₇Sb₉Se₁₀.

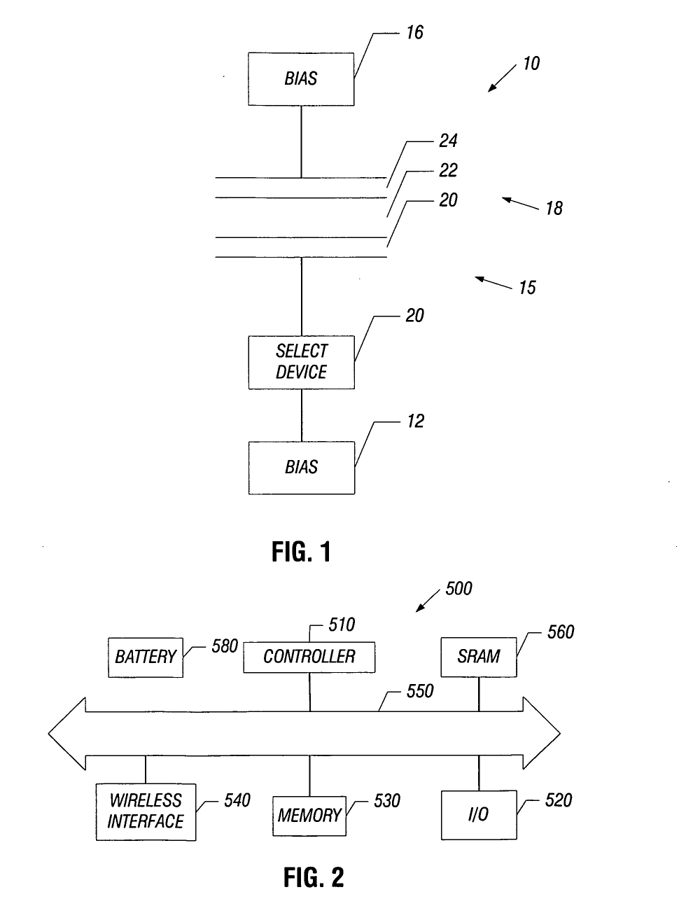

Referring to FIG. 1, a phase change memory 10 may include one or more cells 18. Each cell 18 may include a bias 12 in the form of a column or row bias and a bias 16 in the form of a column or row bias in some embodiments. The cell 18 may include an upper electrode 24, a lower electrode 20, and a chalcogenide alloy material 22 of the type described herein, making up a memory element 15. The arrangement of the cell 18 may be in accordance with any conventional design including those that use lance arrangements, pore arrangements, planar arrangements, lateral arrangements, and those that include ovonic threshold switches.

In some embodiments, a select device 14 may be provided as part of the cell 18. In some cases, the select device 14 may be an ovonic threshold switch, but any other select device may be utilized as well, including a field effect transistor or a diode.

While embodiments are described that involve single level memory cells, the present invention may also be implemented, in some cases, by multilevel memory technologies. Embodiments may include chalcogenide alloys that change phase, as well as amorphous alloys with different detectable threshold voltages.

Examples of phase change materials may include a chalcogenide material or an ovonic material. An ovonic material may be a material that undergoes electronic or structural changes and acts as a semiconductor once subjected to application of a voltage potential, electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, if the memory material 22 is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material 22, in the substantially amorphous state, is greater than the resistance of the memory material in the substantially crystalline state. Accordingly, in this embodiment, the memory material 22 may be adapted to be altered to a particular one of a number of resistance values within a range of resistance values to provide digital or analog storage of information.

Programming of the memory material to alter the state or phase of the material may be accomplished by applying voltage potentials to the electrodes 20 and 24, thereby generating a voltage potential across the memory material 22. An electrical current may flow through a portion of the memory material 22 in response to the applied voltage potentials, and may result in heating of the memory material 22.

This heating and subsequent cooling may alter the memory state or phase of the memory material 22. Altering the phase or state of the memory material 22 may alter an electrical characteristic of the memory material 22. For example, resistance of the material 22 may be altered by altering the phase of the memory material 22. The memory material 64 may also be referred to as a programmable resistive material or simply a programmable resistance material.

In one embodiment, a voltage potential difference of about 0.5 to 1.5 volts may be applied across a portion of the memory material by applying about 0 volts to electrode 20 and about 0.5 to 1.5 volts to an upper electrode 24. A current flowing through the memory material 22 in response to the applied voltage potentials may result in heating of the memory material. This heating and subsequent cooling may alter the memory state or phase of the material.

In a “reset” state, the memory material may be in an amorphous or semi-amorphous state and in a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted.

Due to electrical current, the memory material 64 may be heated to a relatively higher temperature to amorphize memory material and “reset” memory material. Heating the volume or memory material to a relatively lower crystallization temperature may crystallize memory material and “set” memory material. Various resistances of memory material may be achieved to store information by varying the amount of current flow and duration through the volume of memory material, or by tailoring the edge rate of the trailing edge of the programming current or voltage pulse.

The information stored in memory material 64 may be read by measuring the resistance of the memory material. As an example, a read current may be provided to the memory material using opposed electrodes 20, 24 and a resulting read voltage across the memory material may be compared against a reference voltage using, for example, a sense amplifier (not shown). The read voltage may be proportional to the resistance exhibited by the memory storage element.

In order to select a cell 18, the selection device 14 for the selected cell 18 may be operated. The selection device 14 activation allows current to flow through the memory element in one embodiment of the present invention.

In a low voltage or low field regime A, the device 14 is an ovonic threshold switch that is off and may exhibit very high resistance in some embodiments. The off resistance can, for example, range from 100,000 ohms to greater than 10 gigaohms at a bias of half the threshold voltage. The device 14 may remain in its off state until a threshold voltage V_{T} or threshold current I_{T} switches the device 14 to a highly conductive, low resistance on state. The voltage across the device 14 after turn on drops to a slightly lower voltage, called the holding voltage V_{H} and remains very close to the threshold voltage. In one embodiment of the present invention, as an example, the threshold voltage may be on the order of 1.1 volts and the holding voltage may be on the order of 0.9 volts.

After passing through the snapback region, in the on state, the device 14 voltage drop remains close to the holding voltage as the current passing through the device is increased up to a certain, relatively high, current level. Above that current level the device remains on but displays a finite differential resistance with the voltage drop increasing with increasing current. The device 14 may remain on until the current through the device 14 is dropped below a characteristic holding current value that is dependent on the size and the material utilized to form the device 14.

In some embodiments, the higher current density of the device 14, in the on state, allows for higher programming current available to the memory element 15. Where the memory element 15 is a phase change memory, this enables the use of larger programming current phase change memory devices, reducing the need for sub-lithographic feature structures and the commensurate process complexity, cost, process variation, and device parameter variation.

One technique for addressing an array cell 18 of memory 10 uses a voltage V applied to the selected column and a zero voltage applied to the selected row. For the case where the memory 10 is a phase change memory, the voltage V may be chosen to be greater than the device 14 maximum threshold voltage plus the memory element 15 reset maximum threshold voltage, but less than two times the device 14 minimum threshold voltage. In other words, the maximum threshold voltage of the device 14 plus the maximum reset threshold voltage of the element 15 may be less than V and V may be less than two times the minimum threshold voltage of the device 14 in some embodiments. All of the unselected rows and columns may be biased at V/2.

With this approach, there is no bias voltage between the unselected rows and unselected columns. This reduces background leakage current.

After biasing the array in this manner, the memory elements 15 may be programmed and read by whatever means is needed for the particular memory technology involved. A memory element 15 that uses a phase change material may be programmed by forcing the current needed for memory element phase change or the memory array can be read by forcing a lower current to determine the device 15 resistance.

For the case of a phase change memory element, programming a given selected bit in the array can be as follows. Unselected rows and columns may be biased as described for addressing. Zero volts is applied to the selected row. A current is forced on the selected column with a compliance that is greater than the maximum threshold voltage of the device 14 plus the maximum threshold voltage of the element 15. The current amplitude, duration, and pulse shape may be selected to place the memory element 15 in the desired phase and thus, the desired memory state.

Reading a phase change memory element 15 can be performed as follows. Unselected rows and columns may be biased as described previously. Zero volts is applied to the selected row. A voltage is forced at a value greater than the maximum threshold voltage of the device 14, but less than the minimum threshold voltage of the device 14 plus the minimum threshold voltage of the element 15 on the selected column. The current compliance of this forced voltage is less than the current that could program or disturb the present phase of the memory element 15. If the phase change memory element 15 is set, the select device 14 switches on and presents a low voltage, high current condition to a sense amplifier. If the element 15 is reset, a larger voltage, lower current condition may be presented to the sense amplifier. The sense amplifier can either compare the resulting column voltage to a reference voltage or compare the resulting column current to a reference current.

The above-described reading and programming protocols are merely examples of techniques that may be utilized. Other techniques may be utilized by those skilled in the art.

To avoid disturbing a set bit of memory element 15 that is a phase change memory, the peak current may equal the threshold voltage of the device 14 minus the holding voltage of the device 58 that quantity divided by the total series resistance including the resistance of the device 14, external resistance of element 15, plus the set resistance of element 15. This value may be less than the maximum programming current that will begin to reset a set bit for a short duration pulse.

Turning to FIG. 2, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, a wireless interface 540, and a static random access memory (SRAM) 560 and coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), a non-volatile memory such as a flash memory, and/or phase change memory that includes a memory element such as, for example, memory 10 illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O device 520 may deliver a voltage reflecting what is stored as either a digital output (if digital information was stored), or it may be analog information (if analog information was stored).

While an example in a wireless application is provided above, embodiments of the present invention may also be used in non-wireless applications as well.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A phase change memory comprising:
a chalcogenide including selenium and less than about 15 atomic percent of germanium.

2. The phase change memory of claim 1 wherein selenium is from 1 to 15 atomic percent of the chalcogenide.

3. The phase change memory of claim 2 wherein selenium is from 3 to 12 atomic percent of the chalcogenide.

4. The phase change memory of claim 3 wherein the selenium is between about 3 and about 10 atomic percent of the chalcogenide.

5. The phase change memory of claim 1 including between 5 and 15 percent atomic percent germanium.

6. The phase change memory of claim 5 including from 20 to 40 atomic percent tellurium.

7. The phase change memory of claim 6 including between 30 and 60 atomic percent antimony.

8. The phase change memory of claim 1 wherein said chalcogenide is Te₄₈Ge_{41.5}Sb₉Se_{2.5}.

9. The phase change memory of claim 1 wherein said chalcogenide is Te₄₄Ge₃₇Sb₉Se₁₀.

10. The phase change memory of claim 1 including from about 3 and about 10 atomic percent selenium and from 5 to 15 atomic percent germanium.

11. A method comprising:
forming a phase change memory with selenium and less than about 15 atomic percent of germanium.

12. The method of claim 11 including using less than about 15 atomic percent of selenium.

13. The method of claim 12 including using from about 3 to about 10 atomic percent of selenium.

14. The method of claim 13 including using from 20 to 40 atomic percent tellurium.

15. The method of claim 14 including using from 30 to 60 atomic percent of antimony.

16. A system comprising:
a processor; and
a memory coupled to said processor and including a chalcogenide with selenium and less than 15 atomic percent of germanium.

17. The system of claim 16 wherein selenium is from 1 to 15 atomic percent of the chalcogenide.

18. The system of claim 17 wherein the selenium is between about 3 and about 10 atomic percent of the chalcogenide.

19. The system of claim 16 including between 5 and 15 atomic percent germanium.

20. The system of claim 19 including from 20 to 40 atomic percent tellurium.
